(19) United States
(12) Patent Application Publication
(10) Pub. No.: US 2016/0258583 A1
(43) Pub. Date: Sep. 8, 2016

(54) QUANTUM DOTS BASED OPTICAL FILTER

(71) Applicant: Pixtronix, Inc., San Diego, CA (US)

(72) Inventors: Jianru Shi, Haverhill, MA (US); Lu Lu, Medford, MA (US); Yuhong Yao, Wakefield, MA (US); Xiang-Dong Mi, Acton, MA (US); Jignesh Gandhi, Burlington, MA (US); James Eakin, Worchester, MA (US); Waseem Mohammad, Andover, MA (US); Robert Myers, Lowell, MA (US); Nikolay Nemchuk, North Andover, MA (US)

(21) Appl. No.: 14/641,052

(22) Filed: Mar. 6, 2015

(51) Int. Cl. F21K 99/00; C23C 16/455; F21V 9/16

(52) U.S. Cl. CPC F21K 9/56; F21V 9/16; C23C 16/45525; F21Y 2101/02

(57) ABSTRACT

This disclosure provides devices, apparatuses and methods of providing an optical filter with quantum dot films for converting a first wavelength of light to a second wavelength of light. The optical filter includes a plurality of high refractive index layers and a plurality of low refractive index layers alternatingly disposed between the high refractive index layers. Quantum dots are dispersed in either the high refractive index layers or the low refractive index layers. In some implementations, the quantum dots are capable of absorbing blue light and emitting green light. Thus, the optical filter can be part of a red-green-blue lighting device that includes a first blue LED optically coupled with the optical filter to produce green light, a red LED and a second blue LED.

### TECHNICAL FIELD

This disclosure relates to optical filters, and more particularly to incorporation of quantum dots in optical filters for converting blue light to green light for display devices.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

Lighting devices may be used for various display devices, including but not limited to liquid crystal displays (LCDs), organic light emitting diode (OLED) displays, MEMS displays, plasma displays, cathode ray tubes (CRTs), field emission displays, surface-conduction electron-emitter displays and projection displays. The lighting devices may serve as backlighting units for the display devices. Typical backlighting units can include a light source coupled to a light guide through which light travels to a display panel. An optical filter may be placed over the light source to generate a desired optical effect, such as absorbing light having a certain wavelength or wavelength range and allowing passage of a certain wavelength or wavelength range.

### SUMMARY

The systems, methods and devices of this disclosure each have several innovative aspects, no single one of which is solely responsible for the desirable attributes disclosed herein.

One innovative aspect of the subject matter described in this disclosure can be implemented in an apparatus including a substrate having a first surface and a second surface opposite the first surface, a quantum dot film on the first surface of the substrate, and an optical filter on the second surface of the substrate. The optical filter includes a plurality of high refractive index layers, and a plurality of low refractive index layers alternatingly disposed between the high refractive index layers. The plurality of high refractive index layers and the plurality of low refractive index layers are configured to reflect a first wavelength of light. The quantum dot film is capable of absorbing the first wavelength of light and emitting a second wavelength of light.

In some implementations, the first wavelength of light corresponds to a blue wavelength and the second wavelength of light corresponds to a green wavelength. In some implementations, the quantum dot film has a thickness greater than each of the plurality of high refractive index layers and low refractive index layers. In some implementations, the quantum dot film has a thickness between about 360 nm and about 480 nm and includes SiO₂. In some implementations, the first surface faces a viewing side of a display and the second surface faces a rear side of the display. In some implementations, an index of refraction of the high refractive index layers is between about 1.7 and about 2.6, and an index of refraction of the low refractive index layers is between about 1.0 and about 1.6. In some implementations, the thickness of each of the high refractive index layers is between about 40 nm and about 70 nm, and the thickness of each of the low refractive index layers is between about 70 nm and about 120 nm. In some implementations, the apparatus further includes a first blue LED light source, where the first blue LED light source is optically coupled to the optical filter and the quantum dot film, the quantum dot film configured to convert the blue light received from the blue LED light source to green light. In some implementations, the apparatus further includes a second blue LED light source and a red LED light source.

Another innovative aspect of the subject matter described in this disclosure can be implemented in a quantum dot based optical filter including a plurality of high refractive index layers, a plurality of low refractive index layers alternatingly disposed between the high refractive index layers, and a plurality of quantum dots dispersed in the plurality of high refractive index layers or the plurality of low refractive index layers. The plurality of high refractive index layers and the plurality of low refractive index layers are configured to reflect a first wavelength of light. The quantum dots are capable of absorbing the first wavelength of light and emitting a second wavelength of light.

In some implementations, the first wavelength of light corresponds to a blue wavelength and the second wavelength of light corresponds to a green wavelength. In some implementations, a transmission of the blue wavelength through the optical filter is less than about 5% and a transmission of the green wavelength through the optical filter is greater than about 80%. In some implementations, the plurality of high refractive index layers include at least 3 high refractive index layers and the plurality of low refractive index layers include at least 3 low refractive index layers.

Another innovative aspect of the subject matter described in this disclosure can be implemented in an apparatus including a substrate having a first surface and a second surface opposite the first surface, means for converting a first wavelength light to a second wavelength of light, the converting means positioned on the first surface of the substrate, and means for reflecting the first wavelength of light, the reflecting means positioned on the second surface of the substrate. The reflecting means includes a plurality of high refractive index layers and a plurality of low refractive index layers alternatingly disposed between the high refractive index layers, where the plurality of high refractive index layers and the plurality of low refractive index layers are configured to reflect the first wavelength of light.

In some implementations, the first wavelength of light corresponds to a blue wavelength and the second wavelength of light corresponds to a green wavelength. In some implementations, the converting means includes a plurality of quantum dots. In some implementations, an index of refraction of the high refractive index layers is between about 1.7 and about 2.6, and an index of refraction of the low refractive index layers is between about 1.0 and about 1.6.

Another innovative aspect of the subject matter described in this disclosure can be implemented in a method of manufacturing a quantum dot based optical filter. The method includes forming a first high refractive index layer on a substrate, forming a first low refractive index layer on the first high refractive index layer, forming a second high refractive index layer on the first low refractive index layer, the second high refractive index layer being identical or substantially identical in thickness and composition as the first high refractive index layer, and forming a second low refractive index layer on the second high refractive index layer, the second low refractive index layer being identical or substantially identical in thickness and composition as the first low refractive index layer. Each of the high refractive index layers or each of the low refractive index layers include a plurality of quantum dots dispersed therein, the quantum dots capable of absorbing a first wavelength of light and emitting a second wavelength of light.

In some implementations, the method includes forming a third high refractive index layer on the second low refractive index layer, the third high refractive index layer being identical or substantially identical in thickness and composition with the first high refractive index layer and forming a third low refractive index layer on the third high refractive index layer, the third low refractive index layer being identical or substantially identical in thickness and composition with the first low refractive index layer. In some implementations, the first wavelength of light corresponds to a blue wavelength and the second wavelength of light corresponds to a green wavelength. In some implementations, the plurality of high refractive index layers and the plurality of low refractive index layers are configured to reflect a first wavelength of light.

Details of one or more implementations of the subject matter described in this disclosure are set forth in the accompanying drawings and the description below. Other features, aspects and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual actuator shutter assembly.

FIG. 3 shows a schematic diagram of an example quantum dot for converting blue light to green light.

FIG. 4 shows a schematic diagram of an example lighting device including a quantum dot based optical filter.

FIG. 5 shows a cross-sectional view of an example quantum dot based optical filter.

FIG. 6A shows a cross-sectional view of an example optical filter including quantum dots.

FIG. 6B shows a cross-sectional view of an example optical filter behind a thick quantum dot film.

FIG. 6C shows a cross-sectional view of an example optical filter in front of a thick quantum dot film.

FIG. 7 shows a flow diagram illustrating an example process for manufacturing a quantum dot based optical filter.

FIGS. 8A and 8B show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. The concepts and examples provided in this disclosure may be applicable to a variety of displays, such as liquid crystal displays (LCDs), organic light-emitting diode (OLED) displays, field emission displays, and electromechanical systems (EMS) and microelectromechanical (MEMS)-based displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

An optical filter for a lighting device can include a multilayer thin film stack. The multilayer thin film stack can include a plurality of high refractive index layers and a plurality of low refractive index layers alternatingly disposed between the high refractive index layers. Quantum dots capable of absorbing a first wavelength of light and emitting a second wavelength of light can be dispersed in either the high refractive index layers or the low refractive index layers. Each layer in the optical filter is configured to reflect the first wavelength of light. In some implementations, the first wavelength can correspond to a blue wavelength of light and the second wavelength can correspond to a green wavelength of light. In some implementations, each layer has a thickness and a refractive index configured to reflect the first wavelength of light. In some implementations, each layer is configured to interferometrically reflect the first wavelength of light. Interferometric reflection can occur when the layer has dimensions and a refractive index for selectively reflecting a wavelength of light according to the principles of optical interference. Interferometric reflection can occur according to the equation d*n=¼*λ, where d represents the thickness of the layer, n represents the refractive index of the layer and λ represents the wavelength of the first wavelength of light. In some implementations, the optical filter is part of a backlighting unit for the lighting device, where the backlighting unit includes a light source for emitting the first wavelength of light and includes the optical filter over the light source. The optical filter is configured to substantially convert the first wavelength of light to the second wavelength of light.

Particular implementations of the subject matter described in this disclosure can be implemented to realize one or more of the following potential advantages. The quantum dot based optical filter having alternating high refractive index layers and low refractive index layers can efficiently convert a wavelength or wavelength range of a certain color to a wavelength or wavelength range of another color. Specifically, the quantum dot based optical filter can efficiently convert blue light to green light. The increased conversion efficiency can increase wall plug efficiency for green light by using a blue LED light source with the optical filter, thereby leveraging the high wall plug efficiency of the blue LED light source. The improved wall plug efficiency for green light can be implemented in a lighting device having a red LED light source and a blue LED light source to improve wall plug efficiency for white light. Furthermore, the incorporation of quantum dots in the optical filter increases the color gamut for a display, for example LCDs. The spectral distribution color peaks are narrower to provide greater color quality and purity over conventional LEDs and phosphors in, for example, LCDs. In addition, having quantum dots dispersed in a matrix of a high/low refractive index material as well as surrounded by additional high/low refractive index layers increase protection against water and air that can significantly degrade the quantum dots upon exposure. Moreover, the incorporation of quantum dots in the optical filter helps to suppress the self-absorption of green light because the total thickness of the layer(s) with incorporated quantum dots is thinner.

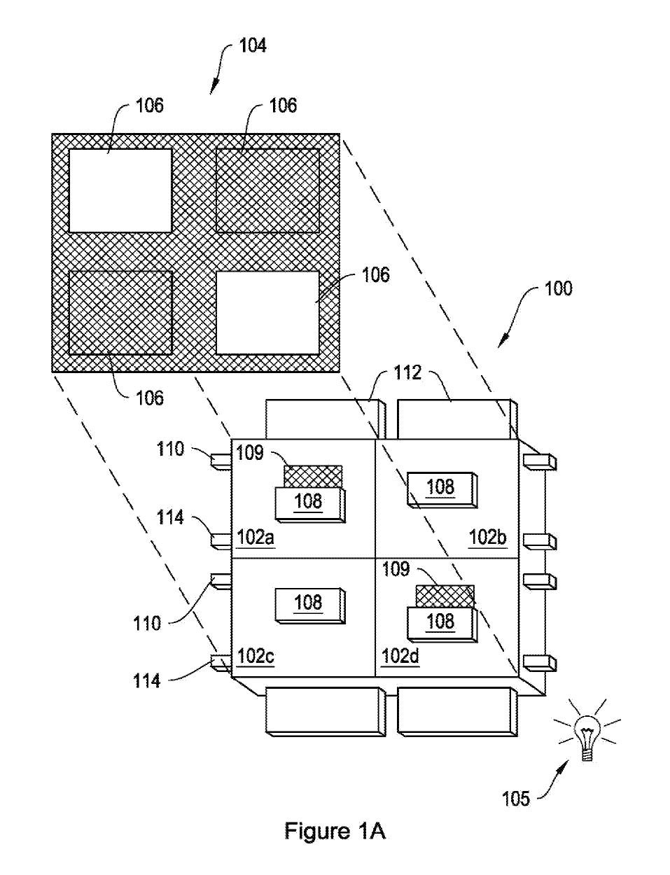

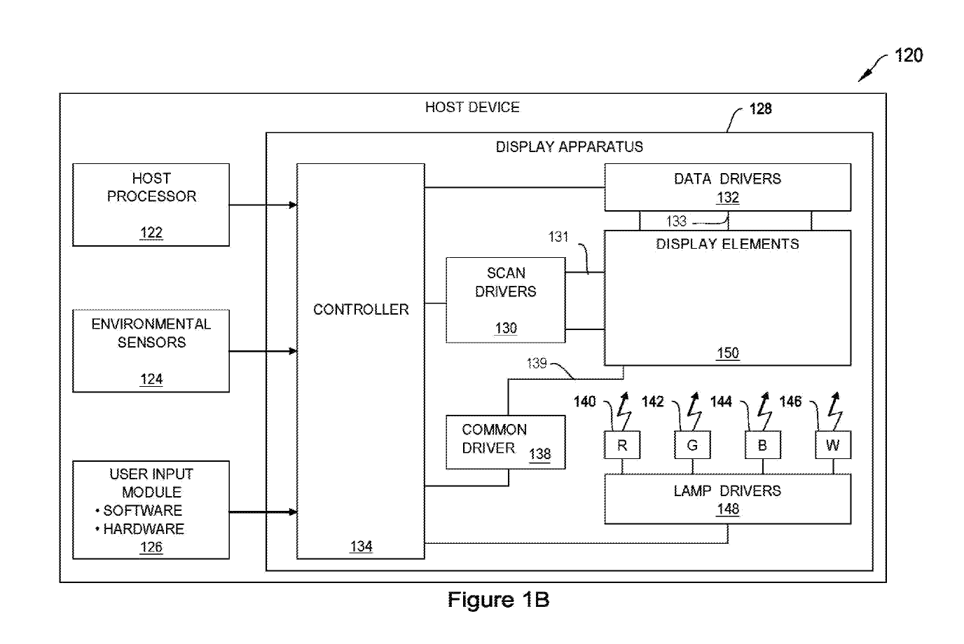

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material.

Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving and/or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for a certain fraction of the image is loaded to the array of display elements 150. For example, the sequence can be implemented to address every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; and/or instructions for the display apparatus 128 for use in selecting an imaging mode.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

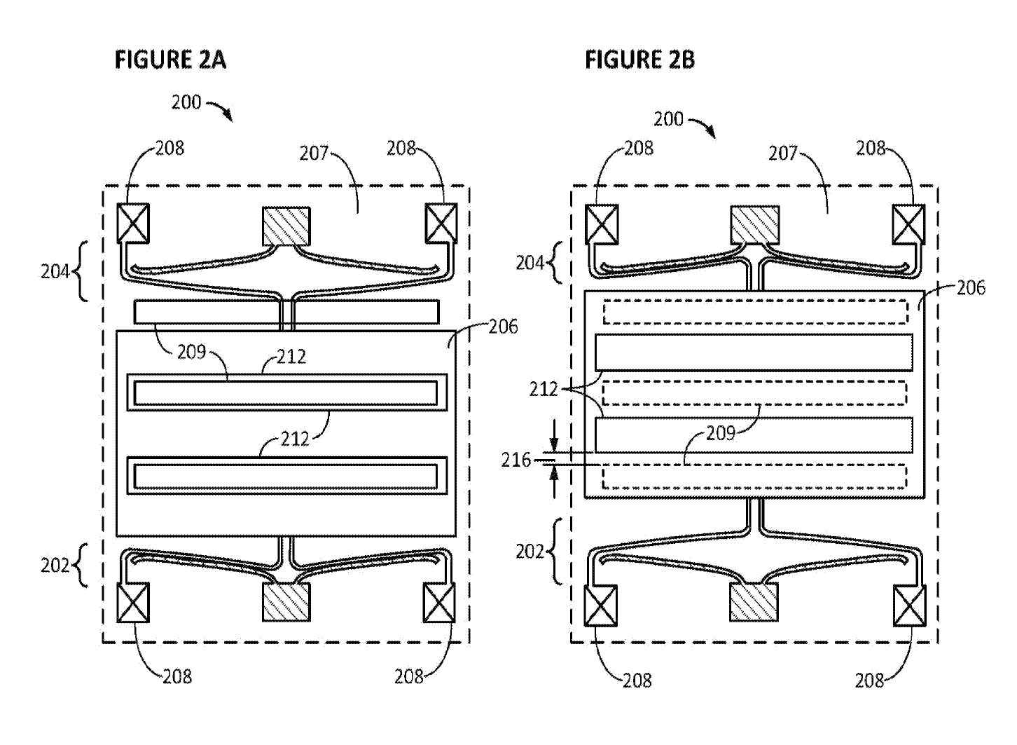

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

Light-emitting diodes (LEDs) are semiconductor light sources that have lower energy consumption, longer lifetime, improved physical robustness, smaller size and faster switching over incandescent light sources. White light can be generated by mixing colors from blue, green and red LED light sources, which can be useful in backlighting units for displays. Backlighting units may be incorporated in a number of different displays, such as LCDs, MEMS-based displays and OLEDs. MEMS-based displays can include those with display apparatuses 100 with light modulators described in FIGS. 1A-1B and dual actuator shutter assemblies 200 described in FIGS. 2A-2B. LED lights can be employed in backlighting units, where the LED lights can include red-green-blue (RGB) LEDs or white LEDs. The white LEDs can be produced using a combination of a blue LED plus a phosphor material. The RGB LED can generate white light by mixing colors using a blue LED, a red LED and a green LED.

The RGB LEDs may provide a better color gamut than the white LEDs. The quality of a display may be measured by a color gamut diagram, where the color gamut can refer to the total space of colors that may be represented by a display. However, the RGB LEDs may be more difficult to implement in a backlighting unit. In addition, the RGB LEDs may not be as energy efficient as the white LEDs. This is because the wall plug efficiency is about 40% for a blue LED and about 30% for a red LED, but about 15% for a green LED. The wall plug efficiency is a measure of energy conversion efficiency for conversion of electrical power to optical power.

Typically, a blue LED can be leveraged to generate white light using either (1) phosphor materials or (2) quantum dots. With phosphor materials, the blue LED generates blue light that can be absorbed by phosphor materials, where the phosphor materials can convert some of the blue light to red, green and yellow light. The red, green, yellow and blue colors can collectively form white light. Obtaining the red, green and blue primary colors for a display can require the use of a color filter. However, the spectral peaks for at least some of the colors may be undesirably broad, resulting in wasted energy and poor color quality. For example, a yellow phosphor is not well-suited for red and green primary colors because of their low spectral weights in the red and green regions.

With quantum dots, blue light can be absorbed by the quantum dots and tuned to emit wavelengths of certain colors. Rather than using phosphor materials, quantum dots can be dispersed in a film so that the film can serve as an optical filter that converts blue light to other wavelengths of light. The quantum dots can emit photons within a narrow spectral distribution based on the properties of the quantum dot, such as its size and material. When the quantum dots emit red and green light, and the red and green light is combined with non-converted blue light, white light is generated with narrow spectral peaks corresponding to red, green and blue primary colors. Compared to phosphors, quantum dots can increase color quality, waste less energy, increase brightness and enable a larger color gamut.

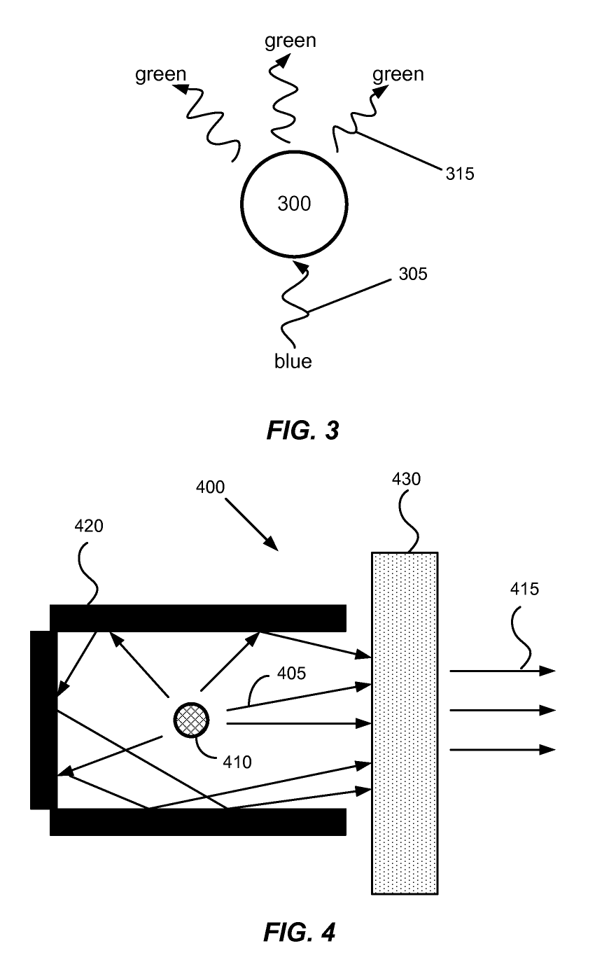

FIG. 3 shows a schematic diagram of an example quantum dot for converting blue light to green light. In some implementations, the quantum dot 300 can be a molecule-sized sphere made of a semiconducting material. The quantum dot 300 can absorb a relatively short wavelength light 305 and emit a narrow spectrum of a longer wavelength light 315. The emitted peak wavelength can depend on the size of the quantum dot. For example, a quantum dot 300 having a diameter of 3 nm can absorb blue light 305 and emit saturated green light 315 with a peak wavelength at 535 nm and a full width at half maximum (FWHM) of about 30 nm. In another example, a quantum dot 300 having a diameter of 7 nm can absorb blue light 305 and emit saturated red light 315 with a peak wavelength at 630 nm and a FWHM of about 35 nm. By tailoring the size of the quantum dot 300, the emitted light 315 can be closely tuned to a desired wavelength within about 1 nm.

Quantum dots 300 are nanocrystals having a diameter less than about 20 nm, or a diameter between about 1 nm and about 10 nm. In some implementations, the optical properties of the quantum dots 300 can be controlled by their size, shape and material. For example, the diameter of the quantum dot 300 can determine the wavelength of the emitted light 315 so that controlling the size of the quantum dot 300 can tune the emission wavelength of the quantum dot 300. In some implementations, the quantum dots 300 can be made of binary compounds. Examples of quantum dots 300 can include but are not limited to lead sulfide (PbS), lead selenide (PbSe), cadmium selenide (CdSe), cadmium sulfide (CdS), indium arsenide (InAs), indium phosphide (InP), zinc sulfide (ZnS) and zinc selenide (ZnSe). In some implementations, the quantum dots 300 can be made of higher order compounds, such as ternary compounds. Ternary compounds can include but is not limited to cadmium selenium telluride (CdSeTe), mercury cadmium telluride (CdHgTe) and zinc cadmium selenide (ZnCdSe). In some implementations, the quantum dots 300 can have a core-shell structure, such as CdSe in the core and ZnS in the shell.

Large batches of quantum dots may be synthesized via colloidal synthesis and incorporated in a film. The film can serve as an optical filter or as part of an optical filter. However, quantum dots may be sensitive to exposure to ambient conditions, including exposure to heat, water and air. Since the performance of the quantum dots can degrade with exposure to heat, water and air, sealing the quantum dots in the film can be important for preserving the reliability and lifetime of the optical filter.

FIG. 4 shows a schematic diagram of an example lighting device including a quantum dot based optical filter. The lighting device 400 can be part of a backlighting unit, where a light source 410 is optically coupled to a quantum dot based optical filter 430. As used herein, “optically coupled” and “optically connected” can refer to elements connected by light. For example, where light transmits from a first element to a second element, the first element can be said to be optically coupled or optically connected to the second element. In some implementations, the light source 410 can be any suitable light source, such as an LED, an incandescent light bulb, a laser, a fluorescent tube, or any other form of a light emitter. In some implementations, the light source 410 can be a blue LED light source that emits blue light within the range of 400 nm and 490 nm.

As illustrated in FIG. 4, the lighting device 400 can include a quantum dot based optical filter 430 over or in front of the light source 410 so that the quantum dot based optical filter 430 is optically coupled with the light source 410. The light source 410 can transmit light 405 and the quantum dot based optical filter 430 can receive the transmitted light 405 and emit light 415. The transmitted light 405 can correspond to a first wavelength or wavelength range of light and the emitted light 415 can correspond to a second wavelength or wavelength range of light. The quantum dot based optical filter 430 can include a plurality of quantum dots dispersed in a suitable matrix material. As discussed below, the plurality of quantum dots may be dispersed in one or more layers.

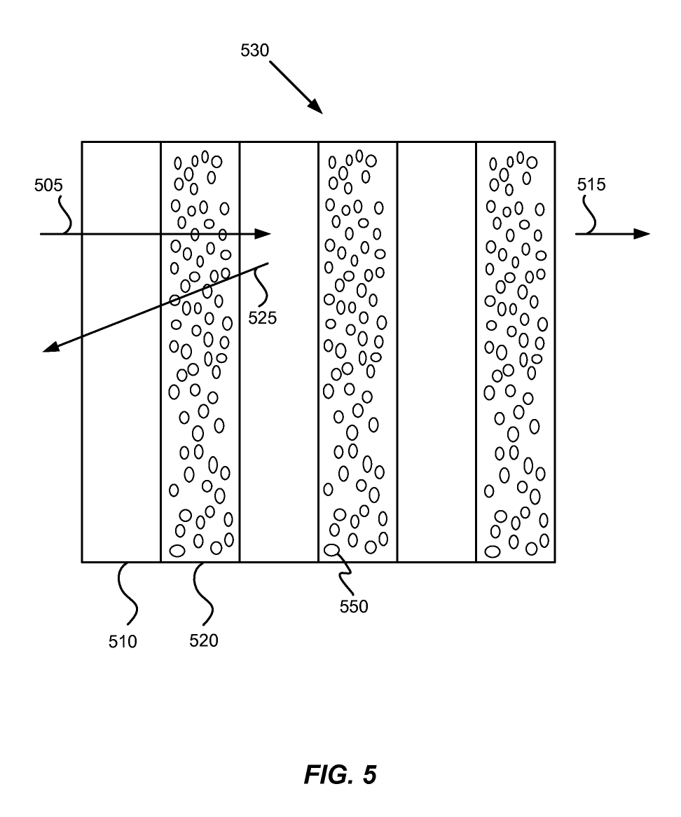

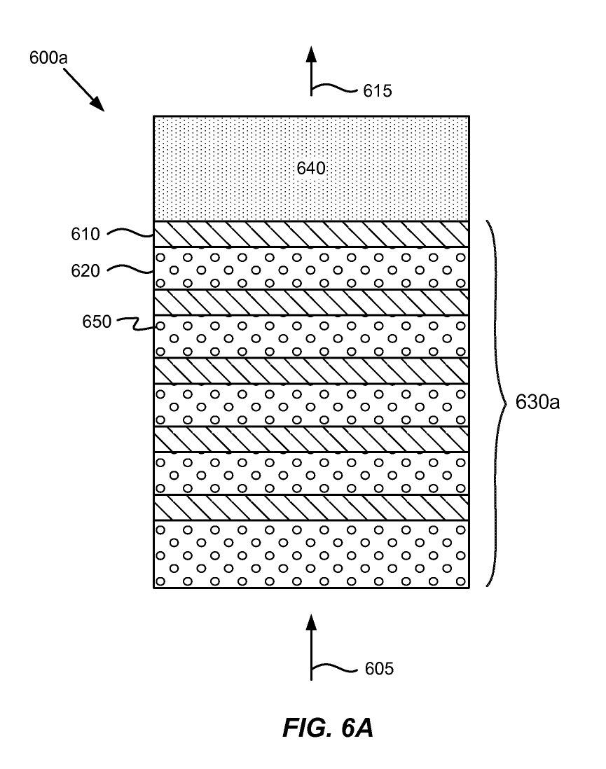

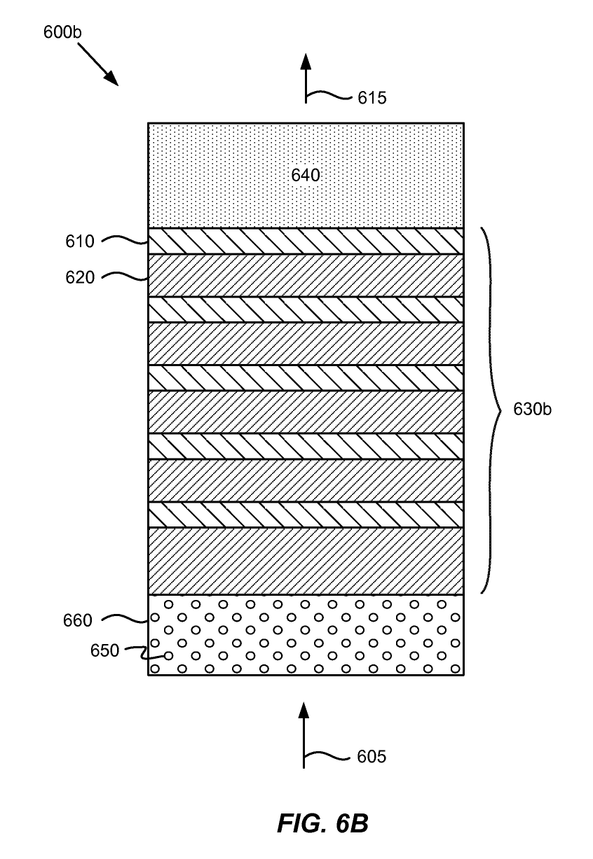

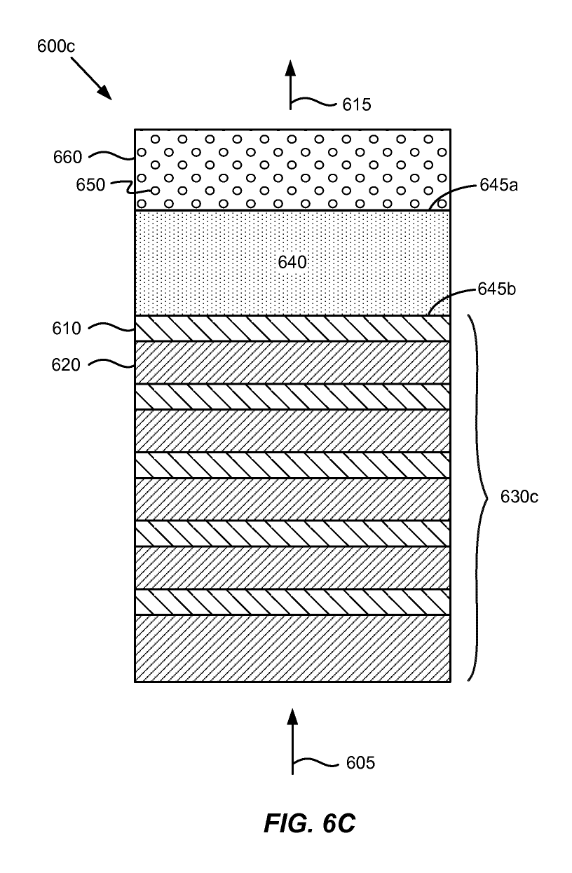

The quantum dot based optical filter 430 can convert a first wavelength, or wavelength range, of light to a second wavelength, or wavelength range, of light. In some implementations, quantum dot based optical filter 430 can convert blue light to white light, where the quantum dot based optical filter 430 converts some of the blue light to red and green light. In some other implementations, the quantum dot based optical filter 430 can convert blue light to green light. The quantum dot based optical filter 430 can generally block out blue light and permit transmission of green light in such implementations. Examples of quantum dot based optical filters 430 are described in more detail with respect to FIGS. 5 and 6A-6C. Thus, a full sequential color scheme can be generated where the red is produced from a red LED light source, blue is produced from a blue LED light source and green is produced from a blue LED light source optically coupled to the quantum dot based optical filter 430.

The lighting device 400 also can include a recycling cavity 420, where the recycling cavity 420 can recycle light 405 transmitted from the light source 410 or reflected from the quantum dot based optical filter 430. The recycling cavity 420 can be optically coupled with the light source 410 and the quantum dot based optical filter 430. In some implementations, the recycling cavity 420 can be formed, placed or positioned to surround the light source 410. The recycling cavity 420 can include a reflective material to reflect transmitted or reflected light 405. The recycling cavity 420 can facilitate multiple passes through the quantum dot based optical filter 430 to increase the likelihood of converting the light 405. Hence, the recycling cavity 420 can increase the conversion efficiency of the lighting device 400.

The quantum dot based optical filter 430 for converting a first wavelength of light to a second wavelength of light can include a multilayer thin film stack. FIG. 5 shows a cross-sectional view of an example quantum dot based optical filter. In FIG. 5, a quantum dot based optical filter 530 can include a plurality of thin film layers 510, 520 with a plurality of quantum dots 550 dispersed in two or more of the thin film layers 510, 520. The quantum dot based optical filter 530 can be a multilayer thin film stack including a plurality of high refractive index layers 510 and a plurality of low refractive index layers 520 alternatingly disposed between the high refractive index layers 510. That way, most or all of the low refractive index layers 520 may be surrounded by high refractive index layers 510, and vice versa. The plurality of quantum dots 550 may be dispersed in either the high refractive index layers 510 or the low refractive index layers 520. As illustrated in the example in FIG. 5, the plurality of quantum dots 550 are dispersed in each of the low refractive index layers 520.

In some implementations, the quantum dot based optical filter 530 may be part of an apparatus, where the apparatus can be a lighting device such as a backlighting unit. The apparatus can include a first blue LED light source and the quantum dot based optical filter 530 optically coupled to the first blue LED light source. The quantum dot based optical filter 530 is configured to convert blue light received from the first blue LED light source to green light. In some implementations, the apparatus further includes a recycling cavity for recycling the blue light. The recycling cavity can be optically coupled to the first blue LED light. In some implementations, the apparatus can further include a second blue LED light source and a red LED light source. The second blue LED light source and the red LED light source can be separate from the recycling cavity and not optically coupled. The apparatus can produce an RGB LED color spectrum. For LCDs, the incorporation of quantum dots in the optical filter 530 improves the color quality and purity, and the quantum dot based optical filter 530 leverages the wall plug efficiency of the blue LED to increase the wall plug efficiency of the green light.

The quantum dots 550 may be capable of absorbing a first wavelength and emitting a second wavelength of light. In some implementations, the properties of the quantum dots 550 may be configured so that the quantum dots 550 absorb blue light and emit green light. The quantum dots 550 may have an average diameter between about 1 nm and about 10 nm, where the diameter may be tuned to absorb blue light and emit green light. The blue light wavelength can be between about 400 nm and about 490 nm, and the green light wavelength can be between about 490 nm and about 570 nm. To illustrate how the diameter can be tuned to emit a certain color, for example, if the quantum dot 550 includes CdSe in the core and ZnS in the shell, the quantum dot 550 having a diameter of 3 nm can emit a saturated green light whereas the quantum dot 550 having a diameter of 7 nm can emit a saturated red light.

The quantum dot based optical filter 530 may be configured to substantially convert the first wavelength to the second wavelength of light. Substantial conversion can refer to greater than about 70% conversion, or greater than about 80% conversion. The conversion efficiency of the quantum dot based optical filter 530 can be improved with multiple passes of light through the quantum dot based optical filter 530.

The quantum dot based optical filter 530 may receive incident light 505 of a first wavelength. The incident light 505 may be converted by the quantum dots 550 so that the quantum dot based optical filter 530 can emit transmitted light 515 of a second wavelength. The incident light 505 that is not converted may be reflected back as reflected light 525. That way, the quantum dot based optical filter 530 may minimize transmission of non-converted light of the first wavelength. In some implementations, the quantum dot based optical filter 530 may be designed to reflect blue light but permit green light to pass through. Thus, the thin film layers 510, 520 may be optimized to reflect blue light and transmit green light, thereby enhancing filter performance. The transmission value of blue light through the quantum dot based optical filter 530 can be less than about 5%, and the transmission value of green light through the quantum dot based optical filter 530 can be greater than about 70%.

To block passage of the first wavelength of light through the quantum dot based optical filter 530, each of the plurality of high refractive index layers 510 and the plurality of low refractive index layers 520 may be configured to reflect the first wavelength of light. The alternating high refractive index layers 510 and low refractive index layers 520 produce a dielectric mirror for reflecting the first wavelength of light and permitting transmission of the second wavelength of light. In some implementations, a thickness and a refractive index of each of the high refractive index layers and a thickness and a refractive index of each of the low refractive index layers are capable of reflecting the blue wavelength. In some implementations, the thickness and refractive index of each of the low refractive index layers are capable of interferometrically reflecting the blue wavelength, meaning that the low refractive index layers are capable of selectively reflecting the blue wavelength according to the principles of optical interference. The thicknesses and the refractive indices of each of the low and each of the high refractive index layers may be configured to interferometrically reflect blue light. Interferometric reflection can occur according to the equation d*n=¼*λ, where d represents the thickness of the layer, n represents the refractive index of the layer and λ represents the wavelength of the first wavelength of light. For interferometrically reflecting the blue wavelength, the equation can be represented as d*n=112.5 nm, for example, where λ is approximately 450 nm. Depending on the refractive index (n) of the selected material, the thickness (d) of the layer can be adjusted to interferometrically reflect blue light. The thicknesses and refractive indices of each of the low and each of the high refractive index layers also are configured to minimize reflection of green light.

The high refractive index layers 510 may be made of a first dielectric material having an index of refraction between about 1.7 and about 2.6. In some implementations, the index of refraction can be between about 1.9 and about 2.4. The low refractive index layers 520 may be made of a second dielectric material having an index of refraction between about 1.0 and about 1.6. In some implementations, the index of refraction can be between about 1.2 and about 1.5. Examples of high refractive index layers 510 include niobium oxide (Nb₂O₅), titanium oxide (TiO₂), silicon nitride (SiNₓ), etc. Examples of low refractive index layers 520 can include silicon oxide (SiO₂).

The thickness of each of the thin film layers 510, 520 can be tuned to interferometrically reflect blue light. In addition, the thickness of each of the thin film layers 510, 520 can be thick enough to protect the quantum dots 550 from moisture and air, and the thickness of the thin film layers 510, 520 can be thin enough to minimize self-absorption of green light. The thickness of each of the thin film layers 510, 520 can be between about 20 nm and about 150 nm. In some implementations, the thickness of each of the high refractive index layers 510 may be between about 40 nm and about 70 nm, and the thickness of each of the low refractive index layers 520 may be between about 70 nm and about 120 nm.

By way of an example, if each of the high refractive index layers 510 include Nb₂O₅ having a refractive index of about 2.4, and the high refractive index layers 510 are optically coupled with a blue LED light source generating light 505 having a wavelength of 440 nm, then the high refractive index layers 510 can each have a thickness of about 46 nm. If each of the low refractive index layers 520 include SiO₂ having a refractive index of about 1.5, and the low refractive index layers 520 are optically coupled with a blue LED light source generating light 505 having a wavelength of 440 nm, then the low refractive index layers can each have a thickness of about 73 nm. In some implementations, one or more of the thin film layers 510, 520 may have a larger thickness corresponding to interferometric reflection at an additional quarter-wavelength of the blue light. Specifically, the equation can be modified to d*n=(x/4)*λ, where x is an odd integer. Thus, a low refractive index layer 520 can have a thickness of about 73 nm, 219 nm and so forth. Even though the thickness of the low refractive index layers 520 can be calculated using the formula above, the actual thickness of the low refractive index layers 520 can be between about 60 nm and about 90 nm, between about 200 nm and about 240 nm, and so forth. In some implementations, the range of thickness for the low refractive index layers 520 can account for the wavelength having a wider band.

The quantum dot based optical filter 530 may include at least three high refractive index layers 510 and at least three low refractive index layers 520. In some implementations, the quantum dot based optical filter 530 may include at least five high refractive index layers 510 and at least five low refractive index layers 520. Each of the high refractive index layers 510 may be identical or substantially identical in composition and thickness, and each of the low refractive index layers may be identical or substantially identical in composition and thickness. This can be true in some implementations for tuning for a particular wavelength of light for the quantum dot based optical filter 530. In some implementations, each of the high refractive index layers 510 may not be identical in thickness and composition, which can be true for wideband applications. In addition, the more layers in the multilayer thin film stack, the more effective the optical filter 530 is at blocking blue light and transmitting green light. More layers increase the chances of the incident light 505 being reflected back by the thin film layers 510, 520 or being absorbed by the quantum dots 550. However, more layers also increase the complexity of fabricating the optical filter 530.

Optimization of the optical filter 530 so that the first wavelength of light is minimally transmitted (or maximally reflected) and the second wavelength of light is maximally transmitted can include tuning the thicknesses of the thin film layers 510, 520, selecting suitable materials for the thin film layers 510, 520 and configuring the number of thin film layers 510, 520. In addition, optimization of the optical filter 530 also can include adjusting the material, size and concentration of the quantum dots 550. In some implementations, the size and material of the quantum dots 550 can be selected to absorb blue light and emit green light. Also, the concentration of the quantum dots 550 can affect the transmission of a wavelength or wavelength range of light.

The transmission values for green light and blue light through various optical filter configurations can be empirically determined. FIGS. 6A-6C illustrate three different optical filter configurations: (1) quantum dot films incorporated as constituent layers of the optical filter, (2) a thick quantum dot film in front of the optical filter and (3) a thick quantum dot film behind the optical filter. As used herein, terms such as “front” and “behind” may be used for ease of describing the figures and to indicate relative positions corresponding to the orientation of the figure on a properly oriented page, and may not reflect the actual orientation of any device as implemented.

FIG. 6A shows a cross-sectional view of an example optical filter including quantum dots. In FIG. 6A, a first structure 600a includes an optical filter 630a on a glass substrate 640. The optical filter 630a can be positioned in front of the glass substrate 640. In some implementations, the glass substrate 640 can be part of a light guide in a lighting device for propagating light towards a display. The display can include an LCD, OLED, or MEMS-based display, such as the display apparatus 100 having light modulators described in FIGS. 1A-1B or MEMS-based displays having dual actuator shutter assemblies 200 described in FIGS. 2A-2B. The optical filter 630a includes a plurality of high refractive index layers 610 and a plurality of low refractive index layers 620 alternatingly disposed between the high refractive index layers 610. As shown in FIG. 6A, the optical filter 630a includes five high refractive index layers 610 and five low refractive index layers 620. Quantum dots 650 are dispersed in each of the low refractive index layers 620 to form quantum dot films, though it is understood that in some implementations the quantum dots 650 can be dispersed in each of the high refractive index layers 610. In some other implementations, the quantum dots 650 may be dispersed in some of the high refractive index layers 610 and some of the low refractive index layers 620. The high refractive index layers 610 can include Nb₂O₅ (n˜2.4) and each have a thickness, for example, between about 30 nm and about 60 nm. The quantum dot films or low refractive index layers 620 can include SiO₂ (n˜1.5) and each have a thickness, for example, between about 60 nm and about 90 nm. In some implementations, a front low refractive index layer 620 can have a larger thickness than the rest of the layers 610, 620 for increased protection from water and air. The front low refractive index layer 620 can include SiO₂ and have a thickness between about 130 nm and about 160 nm. Hence, the total thickness of the optical filter 630a can be between about 520 nm and about 820 nm.

Incident light 605 can travel through a medium such as air before propagating through the optical filter 630a. The incident light 605 can have a wavelength of about 450 nm±15 nm to represent a blue color. The incident light 605 can enter the optical filter 630a through the front low refractive index layer 620, and transmitted light 615 can exit through the glass substrate 640. The optical filter 630a can convert the blue light to green light when the incident light 605 is absorbed by the quantum dot films 620, or the optical filter 630a can reflect the blue light by the high refractive index layers 610 or the low refractive index layers 620. However, some of the blue light may leak or otherwise transmit through the optical filter 630a and the glass substrate 640 without being absorbed or reflected. Moreover, some of the converted green light may be self-absorbed by the optical filter 630a and the glass substrate 640. By way of an example, in FIG. 6A, the transmission value of blue light having a wavelength of about 450 nm±15 nm through the first structure 600a is less than about 5%, .and the transmission value of green light having a wavelength of about 550 nm±15 nm within 70° incidence through the first structure 600a is greater than about 80%.

FIG. 6B shows a cross-sectional view of an example optical filter behind a thick quantum dot film. In FIG. 6B, a second structure 600b includes an optical filter 630b on a glass substrate 640 and a thick quantum dot film 660 on the optical filter 630b. The glass substrate 640 is positioned behind the optical filter 630b and the thick quantum dot film 660 is positioned in front of the optical filter 630b. The optical filter 630b includes a plurality of high refractive index layers 610 and a plurality of low refractive index layers 620 alternatingly disposed between the high refractive index layers 610. The optical filter 630b can have a similar configuration as the optical filter 630a, with high refractive index layers 610 including Nb₂O₅ and each having a thickness between about 30 nm and about 60 nm, low refractive index layers 620 including SiO₂ and each having a thickness of between about 60 nm and about 90 nm and a front low refractive index layer 620 including SiO₂ and having a thickness between about 130 nm and about 160 nm. However, neither the high refractive index layers 610 nor the low refractive index layers 620 include quantum dots 650. Instead, the thick quantum dot film 660 includes quantum dots 650 dispersed in a low refractive index material such as SiO₂ and has a thickness between about 360 and about 480 nm. The total thickness of the optical filter 630b and the thick quantum dot film 660 is between about 880 nm and about 1300 nm.

Incident light 605 enters through the thick quantum dot film 660 and transmitted light 615 exits through the glass substrate 640, where the incident light 605 can have a wavelength of 450 nm±15 nm to represent a blue color. The thick quantum dot film 660 can convert the blue light to green light or reflect the blue light, and the optical filter 630b can reflect the blue light. However, some of the blue light may leak or otherwise transmit through the optical filter 630b and the glass substrate 640 without being absorbed or reflected, and some of the green light may be self-absorbed by the second structure 600b. In FIG. 6B, the transmission value of blue light having a wavelength of about 450 nm±15 nm through the second structure 600b is less than about 7%, and the transmission value of green light having a wavelength of about 550 nm±15 nm within 70° incidence through the second structure 600b is greater than about 60%.

FIG. 6C shows a cross-sectional view of an example optical filter in front of a thick quantum dot film. In FIG. 6C, a third structure 600c can include a glass substrate 640 on a thick quantum dot film 660 and an optical filter 630c on the glass substrate 640. The thick quantum dot film 660 is positioned behind the glass substrate 640 and the optical filter 630c is positioned in front of the glass substrate 640. The optical filter 630c in FIG. 6C has the same configuration as the optical filter 630b in FIG. 6B. In the third structure 600c, however, the thick quantum dot film 660 is positioned behind the glass substrate 640 rather than the thick quantum dot film 660 being positioned in front of the optical filter 630c. The thick quantum dot film 660 includes quantum dots 650 dispersed in a low refractive index material such as SiO₂ and has a thickness between about 360 nm and about 480 nm. The thick quantum dot film 660 is spaced apart from the optical filter 630c by at least a thickness of the glass substrate 640.

Incident light 605 enters through the optical filter 630c and transmitted light 615 exits through the thick quantum dot film 660, where the incident light 605 can have a wavelength of 450±15 nm to represent a blue color. With respect to the transmitted light 615 in FIG. 6C, the transmission value of blue light having a wavelength of about 450 nm±15 nm through the third structure 600c is less than about 7%, and the transmission value of green light having a wavelength of about 550 nm±15 nm within 70° incidence through the third structure 600c is greater than about 70%.

In some implementations, the third structure 600c can be an apparatus including a substrate 640 having a first surface 645a and a second surface 645b opposite the first surface 645a. The apparatus 600c can include a quantum dot film 660 on the first surface 645a and an optical filter 630c on the second surface 645b. The optical filter 630c can include a plurality of high refractive index layers 610 and a plurality of low refractive index layers 620 alternatingly disposed between the high refractive index layers 610. The plurality of high refractive index layers 610 and the plurality of low refractive index layers 620 are configured to reflect a first wavelength of light. The quantum dot film 660 is capable of absorbing the first wavelength of light and emitting a second wavelength of light. In some implementations, the first wavelength of light corresponds to a blue wavelength and the second wavelength of light corresponds to a green wavelength. In some implementations, a thickness and a refractive index of each of the high refractive index layers 610 and a thickness and a refractive index of each of the low refractive index layers 620 are configured to interferometrically reflect the blue wavelength. In some implementations, the quantum dot film 660 has a thickness greater than each of the plurality of high refractive index layers 610 and low refractive index layers 620. In some implementations, the first surface 645a faces a viewing side of a display and the second surface 645b faces a rear side of the display. By being positioned on a side of the substrate 640 that is opposite the optical filter 630c, the quantum dot film 660 can be protected from exposure to ambient conditions.

Table 1 compares the transmission values for each of the structures 600a, 600b and 600c with respect to the angles of incidence. Comparing the structures of FIGS. 6A-6C, the first structure 600a provides greater transmission of green light and provides a relatively comparable amount of leakage of blue light. In addition, the first structure 600a provides better sealing of the quantum dots 650 from exposure to air and water, whereas the second structure 600b and the third structure 600c do not protect the quantum dots 650 as effectively from exposure to air and water. As shown in the first structure 600a in FIG. 6A, the low refractive index layers 620 in the optical filter 630a containing the quantum dots 650 are surrounded not only in a matrix of a low refractive index material, but also by high refractive index layers 610. Such an arrangement provides added protection against ambient conditions. Furthermore, the first structure 600a has a lower total thickness compared to each of the total thicknesses of the second structure 600b and the third structure 600c.

TABLE 1

| | FIG. 6A | FIG. 6A | FIG. 6B | FIG. 6B | | |
|---|---|---|---|---|---|---|
| | Trans. | Trans. | Trans. | Trans. | FIG. 6C | FIG. 6C |
| Angle of | % | % | % | % | Trans. % | Trans. % |
| Incidence | (blue) | (green) | (blue) | (green) | (blue) | (green) |
| 0° | 1% | 98% | 0% | 98% | 0% | 95% |
| 10° | 1% | 98% | 0% | 99% | 0% | 94% |
| 20° | 1% | 95% | 1% | 94% | 0% | 92% |
| 30° | 1% | 91% | 1% | 86% | 0% | 88% |
| 40° | 2% | 88% | 1% | 87% | 1% | 85% |
| 50° | 3% | 89% | 2% | 91% | 2% | 84% |
| 60° | 3% | 91% | 3% | 78% | 3% | 83% |
| 70° | 4% | 90% | 4% | 66% | 4% | 76% |
| 80° | 3% | 70% | 4% | 51% | 3% | 49% |
| Average | 2% | 90% | 2% | 83% | 2% | 83% |

Even if 5% or less of blue light is leaked from the first structure 600a, the impact on the color gamut is negligible. Granted, if some blue light is leaked out, then the green spectra on the color gamut will contain some amount of blue. However, when using a RGB LED color spectrum white balanced at D65, the resulting color shift in the green spectra is less than 0.01 if 5% of blue light is added to the RGB LED color spectrum. The resulting color gamut shrinkage is less than 2%, rendering the impact on the color gamut negligible.

The wall plug efficiency for green light also can be improved using the first structure 600a with a blue LED compared to the wall plug efficiency of a conventional green LED. The wall plug efficiency (WPE) for green light can be calculated as a function of the blue WPE, the blue-to-green conversion efficiency, and the percentage of green light transmission, for example. As discussed earlier, the blue WPE for a blue LED is about 40%, whereas the green WPE for a green LED is about 15%. Table 2 shows the green WPE when using a quantum dot based optical filter with a blue LED as a function of the blue-to-green conversion efficiency. The resulting calculation shows that if the blue-to-green conversion efficiency is greater than 30%, then improvements to the green WPE can be seen.

TABLE 2

| Blue-to-Green | Green WPE Using Quantum Dot Based |
|---|---|
| Conversion Efficiency | Optical Filter with Blue LED |
| 10% | 6% |
| 20% | 12% |
| 30% | 16% |
| 40% | 20% |
| 50% | 24% |
| 60% | 27% |
| 70% | 29% |
| 80% | 31% |
| 90% | 32% |

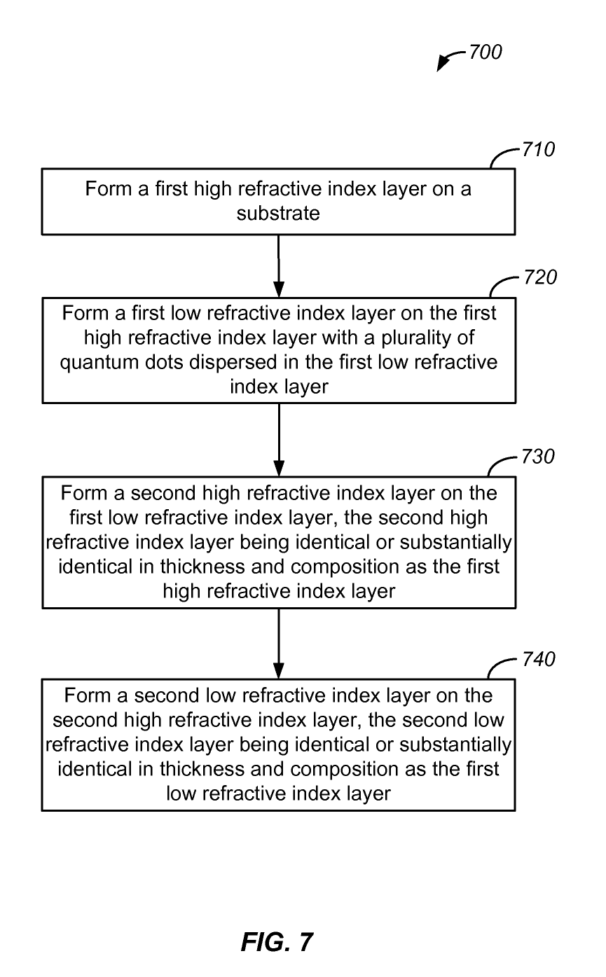

FIG. 7 shows a flow diagram illustrating an example process for manufacturing a quantum dot based optical filter. The process 700 may be performed in a different order or with different, fewer or additional operations.

At block 710, a first high refractive index layer is formed on a substrate. The substrate can include any suitable substrate material, such as glass or plastic. In some implementations, the substrate material can be substantially transparent to visible light. Substantial transparency as used herein may be defined as transmittance of visible light of about 70% or more, such as about 80% or more, or even about 90% or more. Glass substrates (sometimes referred to as glass plates or panels) may be or include a borosilicate glass, a soda lime glass, photoglass, quartz, Pyrex or other suitable glass material. An optical filter can be formed, placed, positioned, or disposed on the substrate. The optical filter may be at least partially transparent to visible light.

The first high refractive index layer may include a dielectric material having a high refractive index. In some implementations, the refractive index can be between about 1.7 and about 2.6, such as between about 1.9 and about 2.4. For example, the dielectric material can include Nb₂O₅ having a refractive index of about 2.4. Depending on the refractive index of the material, the thickness of the first high refractive index layer can be tuned according to the equation d*n=¼*λ, where λ corresponds to a first wavelength of light, such as a blue wavelength. In some implementations, the first high refractive index layer can be between about 40 nm and about 70 nm. The first high refractive index layer can be formed using any suitable deposition techniques known in the art, such as PVD, CVD, PECVD, ALD and spin-coating. Deposition steps may be subsequently followed by masking, patterning, etching, or planarization steps.

At block 720, a first low refractive index layer is formed on the first high refractive index layer with a plurality of quantum dots dispersed in the first low refractive index layer. However, it is understood that in some implementations, the plurality of quantum dots may be dispersed in the first high refractive index layer instead. The quantum dots are capable of absorbing a first wavelength of light and emitting a second wavelength of light. In some implementations, the quantum dots are capable of absorbing a blue wavelength and emitting a green wavelength. The first low refractive index layer may include a dielectric material having a low refractive index. In some implementations, the refractive index can be between about 1.0 and about 1.6, such as between about 1.2 and about 1.5. For example, the dielectric material can include SiO₂ having a refractive index of about 1.5. Depending on the refractive index of the material, the thickness of the first low refractive index layer can be tuned according to the equation d*n=¼*λ, where λ corresponds to the first wavelength of light, such as a blue wavelength. In some implementations, the first low refractive index layer can be between about 70 nm and about 120 nm.

The first low refractive index layer can be formed using any suitable deposition techniques known in the art, such as PVD, CVD, PECVD, ALD and spin-coating. The first low refractive index layer can be manufactured using processes for manufacturing quantum dot films, where colloidal nanoparticles can be prepared and assembled into thin films. In some implementations, the first low refractive index layer can be formed using ALD. By way of an example, large batches of CdSe quantum dots may be formed via colloidal synthesis to form CdSe nanocrystal films, and ALD can be used to infiltrate the CdSe nanocrystal films, where the open crystalline structure of CdSe nanocrystal films allows for gaseous diffusion of ALD precursor molecules. Zinc oxide (ZnO) ALD can be used to form core/shell quantum dots of CdSe/ZnO thin films. In some other implementations, the first low refractive index layer can be formed with quantum dots using spin-coating, dual injection and inkjet printing.

At block 730, a second high refractive index layer is formed on the first low refractive index layer, where the second high refractive index layer is identical or substantially identical in thickness and composition as the first high refractive index layer. Thus, the second high refractive index layer can be deposited under identical or substantially identical conditions as the first high refractive index layer. “Substantially identical” can refer to a deviation of a 10% or less difference than the layer being compared to, or a 5% or less difference than the layer being compared to. In some implementations, the second high refractive index layer can include Nb₂O₅ having a thickness between about 40 nm and about 70 nm. Additional high refractive index layers may be repeatedly formed following each low refractive index layer, thereby forming a third high refractive index layer, a fourth high refractive index layer and so forth.

At block 740, a second low refractive index layer is formed on the second high refractive index layer, where the second low refractive index layer is identical or substantially identical in thickness and composition as the first low refractive index layer. Accordingly, the second low refractive index layer can be deposited under identical or substantially identical conditions as the first low refractive index layer. For example, the second low refractive index layers can be deposited using ALD as described above with respect to block 720. A plurality of quantum dots also may be dispersed in the second low refractive index layer, where the quantum dots are capable of absorbing the first wavelength of light and emitting the second wavelength of light. Additional low refractive index layers may be repeatedly formed following each high refractive index layer, thereby forming a third low refractive index layer, a fourth low refractive index layer and so forth.

In some implementations, the process 700 further includes forming a third high refractive index layer on the second low refractive index layer, where the third high refractive index layer is identical or substantially identical in thickness and composition as the first high refractive index layer. The process 700 also can include forming a third low refractive index layer on the third high refractive index layer, where the third low refractive index layer is identical or substantially identical in thickness and composition as the first low refractive index layer.

The resulting multilayer thin film stack on the substrate forms an optical filter capable of converting the first wavelength of light to the second wavelength of light. The optical filter includes alternating layers of high refractive index layers and low refractive index layers that can function as a dielectric mirror to the first wavelength of light. For example, the high refractive index layers and the low refractive index layers can be configured to reflect the first wavelength of light.

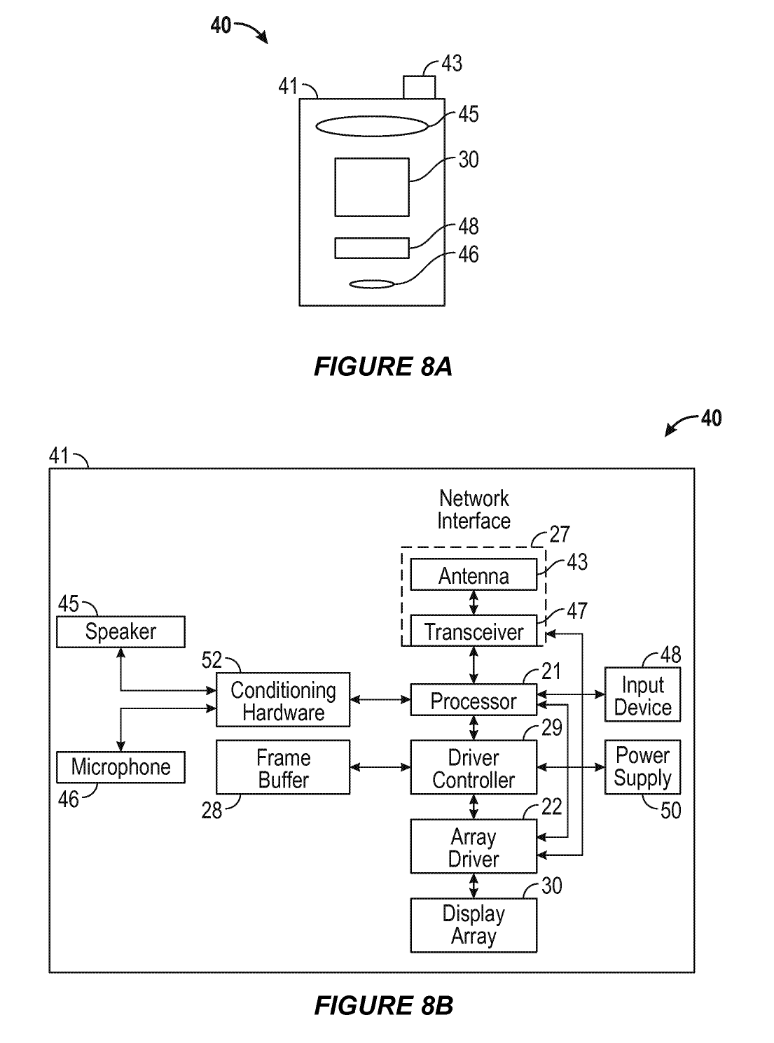

FIGS. 8A and 8B show system block diagrams of an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 8B. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 8A, can be capable of functioning as a memory device and be capable of communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to any of the IEEE 16.11 standards, or any of the IEEE 802.11 standards. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29 is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40. Additionally, in some implementations, voice commands can be used for controlling display parameters and settings.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower,” “front” and “behind,” “above” and “below” and “over” and “under,” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
a substrate having first surface and a second surface opposite the first surface;
a quantum dot film on the first surface of the substrate, the quantum dot film capable of absorbing a first wavelength of light and emitting a second wavelength of light; and
an optical filter on the second surface of the substrate, the optical filter comprising:
a plurality of high refractive index layers;
a plurality of low refractive index layers alternatingly disposed between the high refractive index layers, wherein the plurality of high refractive index layers and the plurality of low refractive index layers are configured to reflect the first wavelength of light.

2. The apparatus of claim 1, wherein the first wavelength of light corresponds to a blue wavelength and the second wavelength of light corresponds to a green wavelength.

3. The apparatus of claim 1, wherein the quantum dot film has a thickness greater than each of the plurality of high refractive index layers and low refractive index layers.

4. The apparatus of claim 1, wherein the quantum dot film has a thickness between about 360 nm and about 480 nm and includes SiO₂.

5. The apparatus of claim 1, wherein the first surface faces a viewing side of a display and the second surface faces a rear side of the display.

6. The apparatus of claim 1, further comprising:
a first blue LED light source, wherein the first blue LED light source is optically coupled to the optical filter and the quantum dot film, the quantum dot film configured to convert the blue light received from the blue LED light source to green light.

7. The apparatus of claim 6, further comprising:
a second blue LED light source; and
a red LED light source.

8. The apparatus of claim 1, wherein an index of refraction of the high refractive index layers is between about 1.7 and about 2.6, and an index of refraction of the low refractive index layers is between about 1.0 and about 1.6.

9. The apparatus of claim 1, wherein a thickness of each of the high refractive index layers and the low refractive index layers is between about 20 nm and about 150 nm.

10. The optical filter of claim 9, wherein the thickness of each of the high refractive index layers is between about 40 nm and about 70 nm, and the thickness of each of the low refractive index layers is between about 70 nm and about 120 nm.

11. The optical filter of claim 1, wherein each of the high refractive index layers includes at least one of Nb₂O₅ and TiO₂, and each of the low refractive index layers includes at least SiO₂.

12. The apparatus of claim 1, further comprising:
a display;
a processor capable of communicating with the display, the processor being capable of processing image data; and
a memory device capable of communicating with the processor.

13. The apparatus of claim 12, further comprising:
a driver circuit capable of sending at least one signal to the display element; and
a controller capable of sending at least a portion of the image data to the driver circuit.

14. The apparatus of claim 12, further comprising:
an image source module capable of sending the image data to the processor, wherein the image source module includes at least one of a receiver, transceiver and transmitter.

15. The apparatus of claim 12, further comprising:
an input device capable of receiving input data and communicating the input data to the processor.

16. A quantum dot based optical filter, comprising:
a plurality of high refractive index layers;
a plurality of low refractive index layers alternatingly disposed between the high refractive index layers, wherein the plurality of high refractive index layers and the plurality of low refractive index layers are configured to reflect a first wavelength of light; and
a plurality of quantum dots dispersed in a plurality of layers, the plurality of layers selected from a group consisting of: the plurality of high refractive index layers and the plurality of low refractive index layers, the quantum dots capable of absorbing the first wavelength of light and emitting a second wavelength of light.

17. The optical filter of claim 16, wherein the first wavelength of light corresponds to a blue wavelength and the second wavelength of light corresponds to a green wavelength.

18. The optical filter of claim 17, wherein a transmission of the blue wavelength through the optical filter is less than about 5% and a transmission of the green wavelength through the optical filter is greater than about 80%.

19. The optical filter of claim 16, wherein each of the low refractive index layers is identical or substantially identical in thickness and composition, and each of the high refractive index layers is identical or substantially identical in thickness and composition.

20. The optical filter of claim 16, wherein the plurality of high refractive index layers include at least 3 high refractive index layers and the plurality of low refractive index layers include at least 3 low refractive index layers.

21. An apparatus comprising:
a substrate having a first surface and a second surface opposite the first surface;
means for converting a first wavelength light to a second wavelength of light, the converting means positioned on the first surface of the substrate; and
means for reflecting the first wavelength of light, the reflecting means positioned on the second surface of the substrate, the reflecting means comprising:
a plurality of high refractive index layers; and
a plurality of low refractive index layers alternatingly disposed between the high refractive index layers, wherein the plurality of high refractive index layers and the plurality of low refractive index layers are configured to reflect the first wavelength of light.

22. The apparatus of claim 21, wherein the first wavelength of light corresponds to a blue wavelength and the second wavelength of light corresponds to a green wavelength.

23. The apparatus of claim 21, wherein the converting means includes a plurality of quantum dots.

24. The apparatus of claim 21, wherein an index of refraction of the high refractive index layers is between about 1.7 and about 2.6, and an index of refraction of the low refractive index layers is between about 1.0 and about 1.6.

25. A method of manufacturing a quantum dot based optical filter, comprising:
forming a first high refractive index layer on a substrate;
forming a first low refractive index layer on the first high refractive index layer;
forming a second high refractive index layer on the first low refractive index layer, the second high refractive index layer being identical or substantially identical in thickness and composition as the first high refractive index layer; and
forming a second low refractive index layer on the second high refractive index layer, the second low refractive index layer being identical or substantially identical in thickness and composition as the first low refractive index layer, wherein each of the high refractive index layers or each of the low refractive index layers include a plurality of quantum dots dispersed therein, the quantum dots capable of absorbing a first wavelength of light and emitting a second wavelength of light.

26. The method of claim 25, further comprising:
forming a third high refractive index layer on the second low refractive index layer, the third high refractive index layer being identical or substantially identical in thickness and composition with the first high refractive index layer; and
forming a third low refractive index layer on the third high refractive index layer, the third low refractive index layer being identical or substantially identical in thickness and composition with the first low refractive index layer.

27. The method of claim 25, wherein the first wavelength of light corresponds to a blue wavelength and the second wavelength of light corresponds to a green wavelength.

28. The method of claim 25, wherein the plurality of high refractive index layers and the plurality of low refractive index layers are configured to reflect a first wavelength of light.

29. The method of claim 25, wherein an index of refraction of the high refractive index layers is between about 1.7 and about 2.6, and an index of refraction of the low refractive index layers is between about 1.0 and about 1.6.

30. The method of claim 25, wherein each of the high refractive index layers and the low refractive index layers are deposited using atomic layer deposition.
